(19) United States
(12) Patent Application Publication
(10) Pub. No.: US 2012/0025343 A1
(43) Pub. Date: Feb. 2, 2012

(54) THERMOELECTRIC DEVICE HAVING A VARIABLE CROSS-SECTION CONNECTING STRUCTURE

(76) Inventors: Philip J. Kuekes, Menlo Park, CA (US); Alexandre M. Bratkovski, Mountain View, CA (US); Hans S. Cho, Palo Alto, CA (US); Nathaniel J. Quitoriano, Pacifica, CA (US); Theodore I. Kamins, Palo Alto, CA (US); R. Stanley Williams, Portola Valley, CA (US)

(21) Appl. No.: 13/262,799

(22) PCT Filed: Apr. 15, 2009
(86) PCT No.: PCT/US2009/040690

§ 371 Date: Oct. 3, 2011

(51) Int. Cl. H01L 29/66; H01L 35/34

(52) U.S. Cl. 257/467; 438/54; 257/E29.347; 257/E21.002

(57) ABSTRACT

A thermoelectric device having a variable cross-section connecting structure includes a first electrode, a second electrode, and a connecting structure connecting the first electrode and the second electrode. The connecting structure has a first section and a second section. The width of the second section is greater than the width of the first section, and the width of the first section is less than a width that is approximately equivalent to a phonon mean free path through the first section.

### BACKGROUND

Thermoelectric devices use the Seebeck effect for generating electric power from a temperature gradient across the thermoelectric devices. Conversely, thermoelectric devices use the Peltier effect for creating a temperature gradient between the sides of the thermoelectric devices through use of electric power.

The efficiency of a thermoelectric device is measured in terms of ZT, which is the dimensionless figure of merit, defined by,

$$ZT = \frac{{S}^{2} σ}{k} T , \qquad Equation ( 1 )$$

where S is the thermoelectric power, σ is the electrical conductivity, k is the thermal conductivity, and T is the temperature of the thermoelectric device. The thermoelectric power (S), is defined by,

$$S = \frac{\partial V}{\partial T} , \qquad Equation ( 2 )$$

where V is the thermoelectric voltage produced per degree temperature (T) difference.

Thermoelectric devices are known to harvest energy that would otherwise be wasted as heat. The efficiency of thermoelectric devices in harvesting heat energy is generally low.

### BRIEF DESCRIPTION OF THE DRAWINGS

Embodiments are illustrated by way of example and not limited in the following figure(s), in which like numerals indicate like elements, in which:

FIG. 1 illustrates a cross-sectional side view of a portion of a thermoelectric device, according to an embodiment of the invention;

FIG. 2 illustrates a cross-sectional side view of a portion of a thermoelectric device, according to another embodiment of the invention;

FIG. 3 illustrates a cross-sectional side view of a portion of a thermoelectric device, according to a further embodiment of the invention;

FIG. 4 illustrates a cross-sectional side view of a thermoelectric device, according to a further embodiment of the invention; and

FIG. 5 illustrates a flow diagram of a method of fabricating the thermoelectric devices depicted in FIGS. 1-4, according to an embodiment of the invention.

### DETAILED DESCRIPTION

For simplicity and illustrative purposes, the principles of the embodiments are described by referring mainly to examples thereof. In the following description, numerous specific details are set forth in order to provide a thorough understanding of the embodiments. It will be apparent however, to one of ordinary skill in the art, that the embodiments may be practiced without limitation to these specific details. In other instances, well known methods and structures are not described in detail so as not to unnecessarily obscure the description of the embodiments.

Disclosed herein is a thermoelectric device that includes at least one n-type section and at least one p-type section. Each n-type section and each p-type section has a first electrode, a second electrode, and one or more connecting structures that connect the first electrode and the second electrode. The n-type section and the p-type section are connected in series electrically, but in parallel thermally, such that the ends of the thermoelectric device may be at the same temperature. The connecting structure includes at least two sections connected in series, which are configured to substantially minimize phonon conduction between the first electrode and the second electrode while having a proportionately lesser limiting effect on the level of electron conduction through the connecting structure.

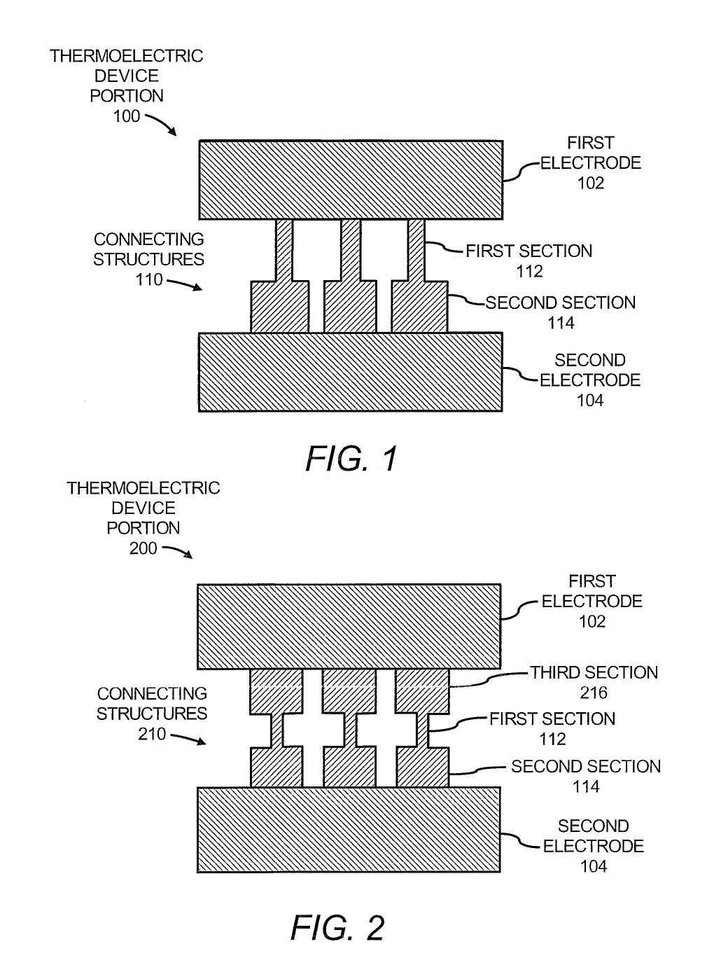

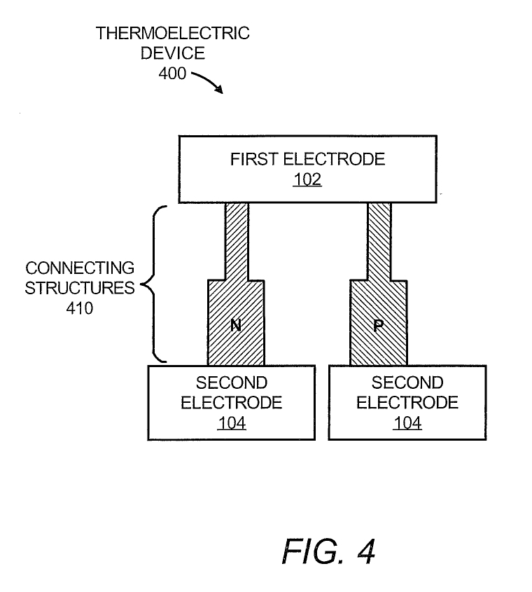

With reference first to FIG. 1, there is shown a cross-sectional side view of a portion 100 of a thermoelectric device, according to an embodiment. The portion 100 shown in FIG. 1 should be understood to represent one of the n-type region and the p-type region of a thermoelectric device, for instance, the thermoelectric device 400 shown in FIG. 4. It should be understood that the portion 100 depicted in FIG. 1 may include additional components and that some of the components described herein may be removed and/or modified without departing from a scope of a thermoelectric device containing the portion 100. For instance, the portion 100 may include additional n-type or p-type regions of a thermoelectric device as shown in the thermoelectric device 400 in FIG. 4.

The portion 100 is configured to either generate electric current from a temperature gradient across the thermoelectric device or to create a temperature gradient across the thermoelectric device through application of an electric current through the thermoelectric device. As depicted in FIG. 1, the thermoelectric device 100 includes a first electrode 102, a second electrode 104 and a plurality of connecting structures 110 connecting the first electrode 102 and the second electrode 104. Each of the connecting structures 110 includes a first section 112 and a second section 114.

The thermoelectric power varies between different materials and, in general, the thermoelectric power for semiconductors is approximately 100 times larger than for metals. In addition, the magnitude of the thermoelectric power for a semiconductor depends on the doping concentration. The thermoelectric power is typically larger for low doped semiconductors and smaller for highly doped semiconductors. In one regard, therefore, the connecting structures 110 are formed of semiconductor material with appropriate doping to produce a sufficient level of thermoelectric power.

According to an embodiment, the first section 112 has a width, which is the dimension that is substantially parallel to the dimension in which the first electrode 102 and the second electrode 104 extend, that substantially limits phonon conduction with a proportionately lesser limiting effect on the level of electron conduction through the first section 112. More particularly, the width of the first section 112 is smaller than a width that is approximately equivalent to a mean free path of phonons and is larger than a width that is approximately equivalent to a mean free path of electrons for the one or more materials forming the first section 112. The mean free path of phonons may be defined as the average distance covered by the phonons between collisions, which is dependent upon the material(s) through which the phonons travel, as well as the temperature of the material(s) at which the mean free path of phonons is determined. In addition, the mean free path of electrons may be defined as the average distance covered by the electrons between collisions, which is dependent upon the material(s) through which the electrons travel, as well as the temperature of the material(s) at which the mean free path of electrons is determined

Generally speaking, the mean free path of electrons is smaller than the mean free path of phonons for most materials and at most temperatures. In addition, as the ratio of the width of the first section 112 to the width equivalent to the mean free path of phonons decreases, phonon scattering increases. Consequently, greatly increased phonon scattering may suppress phonon conduction completely or nearly completely, reducing thermal conductivity. Conversely, electrical conductivity, which occurs through electron or hole carrier movement/mobility in semiconductors, will be substantially less affected as the width of the first section 112 is greater than the width equivalent to the mean free path of electrons for the material forming the first section 112. The width of the first section 112 is thus selected to scatter phonons without substantially negatively impacting electron or hole carrier movement/mobility through the first section 112.

In conventional thermoelectric devices that are typically comprised of structures with larger lateral dimensions, electrical conductivity (σ) tracks thermal conductivity (k). In contrast, the first section 112 is able to partially decouple electrical conductivity (σ) from thermal conductivity (k), because in semiconductors, electrical conductivity is primarily due to movement of electrons while thermal conductivity is primarily due to movement of phonons. As the diameter of 112 decreases, the thermal conductivity (k) decreases at a greater rate than electrical conductivity (σ). Consequently, there will be a corresponding increase in efficiency because of the relationship of both to the dimensionless figure of merit (ZT). As such, and as discussed above, the first section 112 has a width that generally results in the movement of phonons to be minimized while still enabling relatively free movement of electrons.

The first section 112 has a length that is calculated based on distances that substantially minimize the amount of electrical resistance in the connecting structures 110. More particularly, the first section 112 has a length that may range from a length equivalent to one or a few mean free paths of phonons for the material forming the first section 112 to a few microns. However, because electrical resistance is directly proportional to the length of the first section 112, a shorter length of the first section 112 is desirable, in order to reduce electrical resistance.

According to an embodiment, the second section 114 has a width that is sized to allow phonon and electron conduction through the second section 114. More particularly, the second section 114 has a width that may be greater than a width that is equivalent to a mean free path of phonons through the material of the second section 114. In one regard, the greater width of the second section 114 serves to reduce its electrical resistance and thus, the second section 114 may have a width that is many times larger than the width that is equivalent to a mean free path of phonons through the material of the second section 114.

In addition, the second section 114 has a length that may be minimized in order to maximize electrical conduction in the connecting structure 110.

By virtue of the first section 112 being in series with the second section 114, the total electrical resistance of the connecting structure 110 may be greatly reduced when compared to a constant cross-section conventional connecting structure of a similar length and a width similar to the first section 112. The connecting structure 110, however, may have a comparable, albeit somewhat lesser, ability to scatter phonons as the constant cross-section conventional connecting structure.

The first section 112 may be formed of, for instance, silicon, germanium, bismuth telluride, lead telluride, bismuth antimonide, lanthanum chalcogenide and the like, including alloys of one or more of these materials.

By way of particular example, the first section 112 and the second section 114 are comprised of silicon. In silicon, the mean free path for phonons is approximately 100 nm while the mean free path for electrons or holes is approximately 10 nm. As such, in this example, the first section 112 has a width that is between 10nm and 100 nm. In addition, the second section 114 has a width that is greater than 100 nm.

By way of a further particular example, each of the connecting structures 110 has a first section 112 that is comprised of germanium and a second section 114 that is comprised of silicon with a heterojunction at the interface. The use of multiple materials in this example facilitates methods of fabricating the connecting structures 110 as described in greater detail herein below.

According to another example, however, the multiple materials may be made to form an alloy during fabrication of the connecting structures 110. In this example, germanium may diffuse at a faster rate into silicon than silicon diffuses into germanium. Where different materials are combined into alloys through interdiffusion in the formation process, an added benefit is that phonon scattering increases significantly in the alloys, in this instance a silicon-germanium alloy. Gradual changes in the composition of the connecting structures 110 may be achieved by varying the ratio of the multiple materials, such as, precursors, during deposition of the connecting structures 110. Furthermore, the strain induced from the different lattice constants of the different materials may also increase phonon scattering.

With reference now to FIG. 2, there is shown a cross-sectional side view of a portion 200 of a thermoelectric device, according to another embodiment. Similar to the portion 100 depicted in FIG. 1, the portion 200 shown in FIG. 2 should be understood to represent one of the n-type region and the p-type region of a thermoelectric device, for instance, the thermoelectric device 400 depicted in FIG. 4. It should be understood that the portion 200 of the thermoelectric device depicted in FIG. 2 may include additional components and that some of the components described herein may be removed and/or modified without departing from a scope of a thermoelectric device containing the portion 200.

As depicted in FIG. 2, the portion 200 includes a first electrode 102, a second electrode 104, and a plurality of connecting structures 210 connecting the first electrode 102 and the second electrode 104. Each of the connecting structures 210 is comprised of a first section 112, a second section 114, and a third section 216.

The connecting structures 210 of the portion 200 performs substantially the same functions as the connecting structures 110 of the portion 100 depicted in FIG. 1. As such, the first section 112 of each of the connecting structures 210 has a width that is smaller than a width that is approximately equivalent to a mean free path of phonons and that is greater than a width that is approximately equivalent to a mean free path of electrons for the one or more materials forming the first section 112. In addition, the second section 114 has a width that is greater than a width that is approximately equivalent to a mean free path of phonons for the one or more materials forming the second section 114. Similarly to the second section 114, the third section 216 also has a width that is greater than a width that is approximately equivalent to a mean free path of phonons for the one or more materials forming the third section 216.

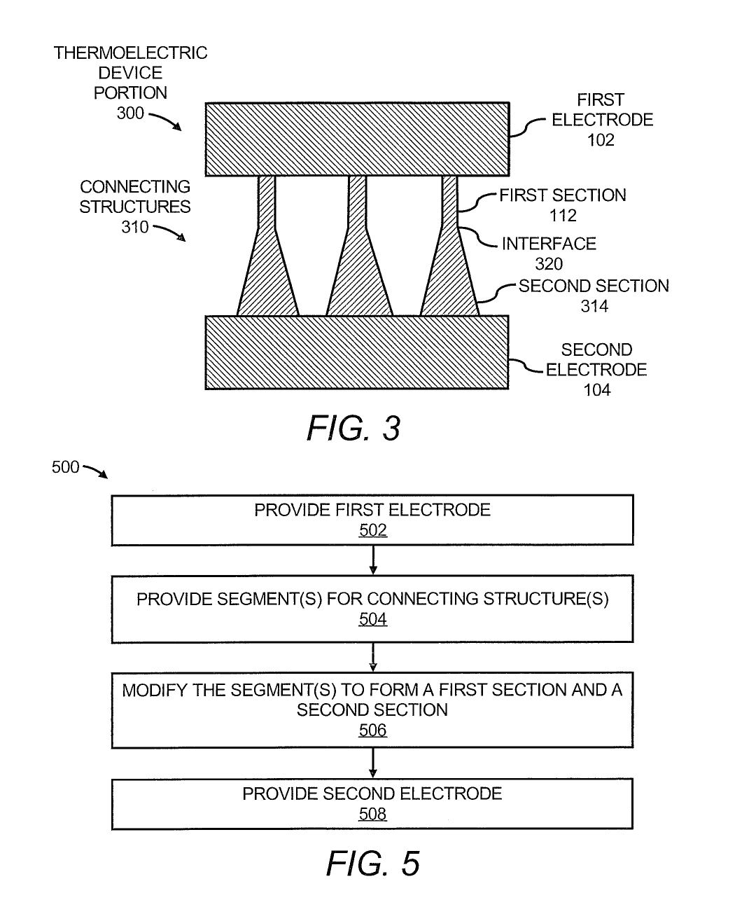

With reference to FIG. 3, there is shown a cross-sectional side view of a portion 300 of a thermoelectric device, according to a further embodiment. Similar to the portion 100 depicted in FIG. 1 and the portion 200 shown in FIG. 2, the portion 300 shown in FIG. 3 should be understood to represent one of the n-type region and the p-type region of a thermoelectric device, for instance, the thermoelectric device 400 depicted in FIG. 4. It should be understood that the portion 300 of the thermoelectric device depicted in FIG. 3 may include additional components and that some of the components described herein may be removed and/or modified without departing from a scope of a thermoelectric device containing the portion 300.

As depicted in FIG. 3, the portion 300 includes a first electrode 102, a second electrode 104 and a plurality of connecting structures 310 connecting the first electrode 102 and the second electrode 104. Each of the connecting structures 310 is comprised of a first section 112 and a second section 314.

The connecting structures 310 perform substantially the same functions as the connecting structures 110, 200 of the sections 100 and 200 depicted in FIGS. 1 and 2. The first section 112 of each of the connecting structures 310 has a width that is smaller than a width that is approximately equivalent to a mean free path of phonons and that is greater than a width that is approximately equivalent to a mean free path of electrons for the one or more materials forming the first section 112. Similarly to the second section 114 depicted in FIGS. 1 and 2, a portion of the second section 314 has a width that is greater than a width that is approximately equivalent to a mean free path of phonons for the one or more materials forming the second section 314. Unlike the second sections 114 depicted in FIGS. 1 and 2, however, the second section 314 has a tapered shape with a base positioned on the second electrode 104 and a top that is connected to and has a similar width to the first section 112. Although the first section 112 and the second section 314 have been depicted as being of the same size at their intersection location 320, it should be understood that one of the first section 112 and the second section 314 may have a larger width than the other one of the first section 112 and the second section 314 without departing from a scope of the connecting structure 310. In this instance, a discontinuity may form at the intersection 320 of the first section 112 and the second section 314.

In an alternate embodiment, although not shown, the first section 112 also has a tapered shape, similar to the second section 314, with a base of the tapered shape being in contact with the first electrode 102. In this embodiment, the tips of the first section 112 and the second section 314 are in contact with each other and at least one of the tips has a width that is smaller than or approximately equivalent to a mean free path of phonons and that is greater than a width that is approximately equivalent to a mean free path of electrons for the one or more materials forming either or both of the first section 112 and the second section 314. In addition, a discontinuity may form at the intersection 320 of the tips of the first section 112 and the second section 314. In this instance, one of the tips may have a width that is greater than a mean free path of phonons for the one or more materials forming that one of the tips.

With reference to FIG. 4, there is shown a cross-sectional side view of a thermoelectric device 400, according to an embodiment. It should be understood that the thermoelectric device 400 depicted in FIG. 4 may include additional components and that some of the components described herein may be removed and/or modified without departing from a scope of the thermoelectric device 400. For instance, the thermoelectric device 400 may include any number of first electrodes, second electrodes, and connecting structures.

As depicted in FIG. 4, the thermoelectric device 400 includes a first electrode 102, a pair of second electrodes 104 and a pair of connecting structures 410. The first electrode 102 is depicted as being connected to the second electrodes 104 by a pair of p-type and n-type connecting structures 410. Although individual ones of the p-type and n-type connecting structures 410 have been depicted as connecting the first electrode 102 to respective second electrodes 104, it should be understood that multiple p-type and n-type connecting structures 410 may connect the first electrode 102 to the second electrodes 104.

Although not explicitly depicted in FIG. 4, the connecting structures 410 of the thermoelectric device 400 may have the shapes of any of the connecting structures 110, 210, and 310 depicted in FIGS. 1-3. In addition, the thermoelectric device 400 may be provided with a mechanical support in addition to the connecting structures 410. The mechanical support may include, for instance, an insulator or a retained layer of oxide from a formation process for the thermoelectric device 400.

Turning now to FIG. 5, there is shown a flow diagram of a method 500 of fabricating the portions 100, 200, and 300 of a thermoelectric device 400 depicted in FIGS. 1-4, according to an embodiment. It should be understood that the method 500 depicted in FIG. 5 may include additional steps and that some of the steps described herein may be removed and/or modified without departing from a scope of the method 500.

At step 502, at least one first electrode 102 may be provided. By way of example, the at least one first electrode 102 may be provided by forming the at least one first electrode 102 through any suitable process, such as one or more of growing, chemical vapor deposition, sputtering, evaporating, patterning, bonding, etc. As another example, the at least one first electrode 102 may be prefabricated and the step of providing may include positioning the at least one first electrode 102 with respect to at least one second electrode 104.

At step 504, one or more segments of connecting structure material may be provided such that as least one of the one or more segments is in contact with the first electrode 102. By way of example, the one or more segments of connecting structure material are provided by forming the one or more segments of connecting structure material through any suitable formation process, such as, growing, catalyzed or uncatalyzed chemical vapor deposition, physical vapor deposition, molecular-beam deposition, molecular-beam epitaxy, laser ablation, sputtering, selective etching, etc. As another example, the one or more segments of connecting structure material may be prefabricated and the step of providing may include positioning the one or more segments of connecting structure material such that at least one of the one or more segments of connecting structure material is positioned in contact with the first electrode 102.

The one or more segments of connecting structure material are comprised of materials that form the connecting structures 110, 210, 310, 410. In this regard, one segment of connecting structure material may comprise one or more materials that form the first section 112, another segment of connecting structure material may comprise one or more materials that form the second section 114, 314, etc. In addition, when a plurality of segments of connecting structure material are provided at step 504, the segments may be diffused together to increase phonon scattering as discussed above. In any event, the different sections of the connecting structure 110, 210, 310, 410 may be formed to have the variable cross-sections during formation of the connecting structures 110, 210, 310, 410.

Optionally, however, at step 506, the one or more segments of connecting structure material may be modified if the variable cross sections are not created during step 504. If performed, the one or more segments of connecting structure material may be modified to form one or more connecting structures 110, 210, 310, 410 having the respective first sections 112 and second sections 114, 314 discussed above. The one or more segments of connecting structure material may be modified through any suitable process or combination of processes, such as one or more of, masking, selective etching, oxidation, diffusion, lithography, etc.

By way of a particular example, one or more connecting structures 110, 210, 310, 410 may be formed from a plurality of segments of connecting structure material comprised of different materials. In this example, one of the segments of connecting structure material comprises germanium and another of the segments of connecting structure material comprises silicon. The segment of connecting structure material comprising silicon is masked to protect it from ambient oxidation. The segments of connecting structure material are then oxidized and germanium dioxide (GeO₂) forms on the segment of connecting structure material comprising germanium, which was not masked. The germanium dioxide on the germanium segment of connecting structure material may then be selectively removed without removing the silicon to form the first section 112, such that, the first section 112 has a width that is smaller than the second section 114, 314. In addition, or alternatively, the germanium dioxide may not be removed from the germanium segment of the connecting structure material because primary conduction, which includes both heat and electrical conduction, will be through unoxidized regions of the connecting structures. As such, the germanium dioxide may be selectively removed to obtain desired conduction properties through the connecting structures. Moreover, the width of the first section 112 formed of the germanium segment of connecting structure material may be reduced to be smaller than the width that is approximately equivalent to a mean free path of phonons through the first section 112.

In another example, the segments of the connecting structures are again formed by Ge and Si, and the segments are oxidized. However, in this example, the Si segments are not protected by masking. Both the Si and Ge segments are oxidized, but at different rates, so that the width of the different segments is reduced by different amounts. In a further refinement of this example, the oxidized structure is then exposed to a selective etchant, such as water, that removes Ge oxide, but not Si oxide. The above-described oxidation and etching process is repeated to reduce the diameter of the Ge segments much more than the diameter of the Si segments, creating the desired variable cross section of the connecting sections.

By way of another particular example, one or more of the connecting structures 110, 210, 310, 410 are formed from a plurality of connecting structure materials comprised of different materials and the first section 112 and the second section 114 are formed through use of the different diffusion rates of the different materials. In this example, one of the segments of connecting structure comprises germanium and another of the segments of connecting structure comprises silicon. Generally speaking, germanium diffuses faster into silicon than silicon diffuses into germanium. This difference in diffusion rates causes net mass transport from the germanium segment of connecting structure to the silicon segment of connecting structure, which causes the initial germanium segment of connecting structure to have a thinner tapered section as compared with the initial silicon segment of connecting structure.

At step 508, at least one second electrode 104 may be provided. By way of example, the at least one second electrode 104 may be provided by forming the at least one second electrode 104 through any suitable process, such as one or more of growing, chemical vapor deposition, sputtering, etching, lithography, etc. Alternately, the at least one second electrode 104 may be provided prior to formation of the connecting structures 110, 210, 310, as described in steps 504 and 506. However, providing the at least one second electrode 104 after the connecting structures 110, 210, 310 are provided may more readily facilitate the formation of the thermoelectric devices 100-400 through processes utilizing catalyzed nanowire growth. For instance, pressure may be varied throughout processes utilizing catalyzed nanowires in order to vary the diameter of the connecting structures 110, 210, 310.

By way of a further particular example, the method 500 may be used to form a thermoelectric device 400 having connecting structures 410 formed to be n-type and p-type semiconductors as shown in FIG. 4. In this example, the thermoelectric device 400 is formed to have a plurality of connecting structures 410, in which, the one or more connecting structures 410 between a particular pair of electrodes 102, 104 are doped to be either p-type or n-type semiconductors and the one or more connecting structures 410 between another particular pair of electrodes 102, 104 are doped to be the other of n-type or p-type semiconductors. More particularly, for instance, the p-type connecting structures 410 may be masked while the n-type connecting structures 410 are being provided and the n-type connecting structures 410 may be masked while the p-type connecting structures 410 are being provided to substantially prevent cross-contamination between the p-type and the n-type connecting structures 410.

What has been described and illustrated herein is an embodiment along with some of its variations. The terms, descriptions and figures used herein are set forth by way of illustration only and are not meant as limitations. Those skilled in the art will recognize that many variations are possible within the spirit and scope of the subject matter, which is intended to be defined by the following claims—and their equivalents—in which all terms are meant in their broadest reasonable sense unless otherwise indicated.

1. A thermoelectric device having a variable cross-section connecting structure, said thermoelectric device comprising:
a first electrode;
a second electrode; and
a connecting structure having a first section and a second section, said connecting structure connecting the first electrode and the second electrode, wherein the first section has a width and the second section has a width, wherein the width of the second section is greater than the width of the first section, and wherein the width of the first section is less than a width that is approximately equivalent to a mean free path of phonons through the first section.

2. The thermoelectric device according to claim 1, wherein the connecting structure has a third section, wherein further the first section is located between the second section and the third section, and wherein the third section has a width greater than the width of the first section.

3. The thermoelectric device according to claim 1, wherein the second section comprises a tapered cross section and wherein the first section is connected to a tip at one end of the tapered cross section.

4. The thermoelectric device according to claim 1, wherein the first section comprises a material selected from the group consisting of silicon, germanium, bismuth telluride, lead telluride, bismuth antimonide, lanthanum chalcogenide and alloys of one or more of silicon, germanium, bismuth telluride, lead telluride, bismuth antimonide, lanthanum chalcogenide.

5. The thermoelectric device according to claim 1, wherein the first section comprises a same material as the second section.

6. The thermoelectric device according to claim 1, wherein the first section comprises a different material than the second section.

7. The thermoelectric device according to claim 1, wherein the first section has a length and the length of the first section is greater than a length that is approximately equivalent to a mean free path of phonons through the first section.

8. The thermoelectric device according to claim 1, wherein the width of the first section and the width of the second section form a transition wherein the transition is untapered.

9. The thermoelectric device according to claim 1, wherein the second section has a nanoscale width.

10. The thermoelectric device according to claim 1, further comprising:
a plurality of second electrodes;
a plurality of connecting structures, each of the plurality of connecting structures having a first section and a second section, each of the plurality of connecting structures connecting the first electrode to the plurality of second electrodes, wherein the width of each of the first sections is less than a width that is approximately equivalent to a mean free path of phonons through the first section, and wherein each of the plurality of connecting structures is either an n-type or a p-type structure.

11. The thermoelectric device according to claim 10, wherein the n-type structures are arranged in groups and connected between the first electrode and a second electrode and the p-type structures are arranged in groups and connected between the first electrode and another second electrode and wherein the groups of n-type structures are alternately arranged with the groups of p-type structures with the first electrode connecting one end of a group of n-type structures with one end of an adjacent group of p-type structures.

12. A method of fabricating a thermoelectric device, said method comprising:
providing a first electrode;
providing a segment of connecting structure material, wherein the segment of connecting structure material is connected to the first electrode, wherein the connecting structure material has a first section and a second section, said connecting structure material is connected to the first electrode, wherein the first section has a width and the second section has a width, wherein the width of the second section is greater than the width of the first section, and wherein the width of the first section is less than a width that is approximately equivalent to a mean free path of phonons through the first section; and
providing a second electrode to be contact with the segment of connecting structure material.

13. The method according to claim 12, wherein providing the segment of the connecting structure material further comprises utilizing catalyzed nanowire growth processes to grow the segment.

14. The method according to claim 13, wherein utilizing catalyzed nanowire growth process further comprises at least one of varying precursors to vary compositions of the segment and varying pressure applied to the segment to vary diameters of the one or more segments.

15. The method according to claim 12, wherein providing the segment of connecting structure material further comprises causing the first section to have a different width as compared with the second section through application of oxidation process.
